(19) United States
(12) Patent Application Publication
(10) Pub. No.: US 2010/0025652 A1
(43) Pub. Date: Feb. 4, 2010

(54) Multiple Quantum-Well Structure, Radiation-Emitting Semiconductor Base and Radiation-Emitting Component

(76) Inventor: Peter Stauss, Pettendorf (DE)

Correspondence Address: COHEN, PONTANI, LIEBERMAN & PAVANE LLP, 551 FIFTH AVENUE, SUITE 1210, NEW YORK, NY, 10176, US

(21) Appl. No.: 12/303,249

(22) PCT Filed: May 4, 2007
(86) PCT No.: PCT/DE2007/000805

§ 371 Date: Jul. 28, 2009

(30) Foreign Application Priority Data
Jun. 2, 2006 (DE) 10 2006 025 964.5

(51) Int. Cl. H01L 29/66

(52) U.S. Cl. 257/13; 257/E29.168

(57) ABSTRACT

A multiple quantum well structure (1) which comprises at least a first quantum well structure (2a) for generating radiation of a first wavelength (6) and at least a second quantum well structure (2b) for generating radiation of a second wavelength (7), which is greater than the first wavelength (6), and is provided for emission of radiation of a main wavelength (14), wherein the second wavelength (7) differs from the first wavelength (6) in such a way that the main wavelength (14) changes only by a predetermined maximum value in the event of a shift in the first wavelength (6) and the second wavelength (7). A radiation-emitting semiconductor body and a radiation-emitting component are furthermore described.

The invention relates to a multiple quantum well structure and to a radiation-emitting semiconductor body comprising the multiple quantum well structure. The invention furthermore relates to a radiation-emitting component having the radiation-emitting semiconductor body.

This patent application claims the priority of German patent application 10 2006 025 964.5, the disclosure content of which is hereby incorporated by reference.

An LED described in the published patent application US 2004/0090779 A1 can generate mixed-colored radiation by means of a first radiation-generating layer embodied as a quantum well structure and a second radiation-generating layer embodied as a quantum well structure. A tunnel barrier is arranged between the two layers. Assuming that the wavelengths of the two radiation-generating layers are fixed, the chromaticity of the mixed-colored radiation can be varied by altering a thickness of the tunnel barrier.

The article by Liang et al. (Dual wavelength InGaN/GaN multi-quantum well LEDs grown by metalorganic vapor phase epitaxy, Journal of Crystal Growth 272 (2004) 333-339) reveals that in an LED having quantum well structures that generate blue and green light, the spectral distribution of the radiation emitted by the LED depends on the number and arrangement of the quantum well structures and on the energization of the LED. By way of example, the increasing energization of an LED having, in a growth direction, three quantum well structures that generate blue light and one quantum well structure that generates green light leads to a shift in the intensity maximum from the blue to the green spectral range.

An undesirable alteration of the chromaticity can occur if an increase in the radiation intensity as intended in numerous applications is to be effected by means of increasing energization. This is because a shift in the wavelength toward shorter wavelengths can be noted as the current intensity increases. This is the case particularly for an LED based on a nitride semiconductor material such as InGaN.

It is an object of the present invention to specify a multiple quantum well structure which is suitable for wavelength-stable operation.

This object is achieved by means of a multiple quantum well structure in accordance with patent claim 1.

Furthermore, it is an object of the present invention to specify a radiation-emitting semiconductor body suitable for wavelength-stable operation.

This object is achieved by means of a radiation-emitting semiconductor body in accordance with patent claim 18.

Furthermore, it is an object of the present invention to specify a radiation-emitting component suitable for wavelength-stable operation.

This object is achieved by means of a radiation-emitting component in accordance with patent claim 21.

The dependent claims relate to advantageous developments and configurations of the invention.

A multiple quantum well structure according to the invention comprises at least a first quantum well structure for generating radiation of a first wavelength and at least a second quantum well structure for generating radiation of a second wavelength, which is greater than the first wavelength, and is provided for emission of radiation of a main wavelength, wherein the second wavelength differs from the first wavelength in such a way that the main wavelength changes only by a predetermined maximum value in the event of a shift in the first wavelength and the second wavelength.

Preferably, the maximum value is approximately 3%. Particularly preferably, the maximum value is less than 3%.

In the present case, the main wavelength should be understood as follows:

in accordance with chromatics, a hue perceived by an observer in the case of polychromatic radiation is assigned a main wavelength, or dominant wavelength, which corresponds to a wavelength of the monochromatic radiation at which the observer would perceive the same hue.

The radiation emitted by the multiple quantum well structure is preferably composed at least of the radiation generated in the first quantum well structure and the radiation generated in the second quantum well structure. If more than two quantum well structures are provided, the total emitted radiation is composed of the radiation generated in the individual quantum well structures. The radiation of the quantum well structure typically has a higher intensity, if the main recombination center is situated in its region. which.

In the present case, the main recombination center indicates the zone in which a majority of electrons and holes recombine radiatively.

In accordance with one preferred variant, the first quantum well structure is arranged on the n-side and the second quantum well structure is arranged on the p-side. Since, as the energization of the multiple quantum well structure increases, the main recombination center is typically shifted in a direction pointing toward the p-side of the multiple quantum well structure, and the second quantum well structure is arranged on the p-side, the second quantum well structure can then, that is to say in the case of greater energization, make a greater contribution to the generation of radiation than the first quantum well structure.

In accordance with a further preferred variant, the shift in the first and second wavelengths takes place in a direction of shorter wavelengths. Such a shift occurs particularly as the energization of the multiple quantum well structure increases. In this case, the extent of the shift is wavelength-dependant, wherein the shift turns out to be all the greater, the greater the wavelength.

The invention is based on the principle that the second wavelength is detuned relative to the first wavelength in such a way that the shift in the first and second wavelengths which occurs in the case of increasing energization, and which would in turn lead to a shift in the main wavelength, can be compensated for by means of the second quantum well structure making a greater contribution to the generation of radiation. The two “shift effects” mentioned (shift in wavelength of the quantum well structures and shift in the main recombination center) are advantageously coupled according to the invention in such a way that wavelength-stable operation of a radiation-emitting component having a multiple quantum well structure as described in the present case is possible even in the case of increasing energization.

In particular, the first wavelength can initially correspond approximately to the main wavelength, wherein the main recombination center is situated in the region of the first quantum well structure. In the case of increasing energization, on the one hand the main recombination center is shifted in a direction of the second quantum well structure, and on the other hand the second wavelength is shifted in a direction of shorter wavelengths. Particularly preferably, the second wavelength is detuned relative to the first wavelength or the main wavelength in such a way that, by means of the shift in wavelength, the second wavelength approximates to the initial value of the first wavelength or the main wavelength if the main recombination center is situated in the region of the second quantum well structure. The shifted second wavelength can then correspond approximately to the main wavelength.

In accordance with one preferred variant, the second wavelength can differ from the first wavelength by a magnitude in the single-digit nanometer range, preferably by approximately 5 nm. This holds true in particular for a main wavelength of 520 nm to 540 nm. In the case of a greater main wavelength, the difference between the first and second wavelengths is preferably greater.

By way of example, the multiple quantum structure can have four quantum well structures, wherein the first three quantum well structures have a band gap in accordance with the first wavelength and the fourth quantum well structure has a band gap in accordance with the second wavelength, which differs from the first wavelength by approximately 5 nm. During operation it is not necessary for all four quantum well structures to contribute to the generation of radiation. If the first three quantum well structures are arranged on the n-side, then in the case of increasing energization, the main recombination center is shifted from the first quantum well structure in a direction of the fourth quantum well structure. The main wavelength can remain essentially unchanged in this case.

The radiation emitted by the multiple quantum well structure is not fixed to a specific main wavelength. However, the main wavelength preferably lies in the short-wave spectral range, for example in the green spectral range, wherein the main wavelength can assume values within the range of between 510 nm and 560 nm. Such a multiple quantum well structure suitable for emission of short-wave radiation can contain, in particular, a nitride-based semiconductor material.

In accordance with one preferred configuration, the multiple quantum well structure has respectively a layer sequence associated with the first and with the second quantum well structure, wherein a barrier layer is arranged between the layer sequences. The charge carriers can pass through the barrier layer from the first quantum well structure to the second quantum well structure, and vice versa. By way of example, electrons can be impressed into the main recombination center from that side of the multiple quantum well structure on which the first quantum well structure is arranged, while holes pass there from the side of the second quantum well structure.

The charge carriers can diffuse or tunnel through the barrier layer.

The thickness of the barrier layer is preferably adapted to the shift in the main recombination center.

The latter can be shifted all the more easily, the thinner the barrier layer.

In accordance with a further preferred embodiment, the thickness of the barrier layer assumes values in the single-digit to two-digit nanometer range. In particular, the thickness is between 4 nm and 25 nm. By means of admixing a suitable material, it is possible to achieve an effective lowering of the band edge and hence a better charge carrier transport across the barrier layer, whereby the barrier layer can be made a few nanometers thicker. One material suitable for lowering the band edge is In, for example.

The barrier layer is preferably n-doped. This advantageously enables a comparatively good charge carrier transport or leads to a reduction of the forward voltage in the finished component. As an alternative, however, the barrier layer can also be undoped. This is the case in particular if the barrier layer already enables a sufficiently good charge carrier transport in the undoped state. The doping can assume values of between 0 and 10¹⁸/cm³.

Particularly preferably, the barrier layer is Si-doped. The Si doping typically lies between 10¹⁷/cm³ and 10¹⁸/cm³. An Si doping that is less than approximately 3-4*10¹⁷/cm³ is preferred according to the invention. By means of a lower doping it is advantageously possible to enlarge an extent of the main recombination center, whereby a plurality of quantum well structures contribute to the radiative recombination.

Furthermore, the barrier layer can contain a nitride-based semiconductor material.

In the present context, a “nitride-based semiconductor material” should be understood to mean a nitride III/V compound semiconductor material, which preferably consists of AlₙGaₘIn₁₋ₙ₋ₘN, where 0≦n≦1, 0≦m≦1 and n+m≦1. In this case, this material need not necessarily have a mathematically exact composition according to the above formula. Rather, it can comprise one or more dopants and additional constitutes which essentially do not change the characteristic physical properties of the AlₒGaₘIn₁₋ₙ₋ₘN material. For the sake of simplicity, however, the above formula only comprises the essential constitutes of the crystal lattice (Al, Ga, In, N), even if these can be replaced in part by small quantities of further substances.

Preferably, the barrier layer contains GaN, InGaN or AlInGaN.

The layer sequences associated with the first and second quantum well structures preferably contain InₓGa₍₁₋ₓ₎N, where 0≦x<1. Such a multiple quantum well structure is suitable for generating short-wave radiation in the green to ultraviolet spectral range. Since it is possible to convert the short-wave radiation into long-wave radiation by means of a converter material, for example, the multiple quantum well structure can advantageously also serve as an active layer for generating long-wave radiation.

The first and second layer sequences respectively have a well layer, the thickness of which is preferably between 1 nm and 5 nm. The depth of the quantum well can be set by means of the thickness of the well layer. The relationship where the wavelength of the radiation is all the longer, the thicker the well layer, holds true. It is conceivable for the different well layers to have different thicknesses.

The multiple quantum well structure according to the invention is particularly suitable for energization in the single-digit to two-digit milliampere range, preferably between more than 0 mA and 15 mA. The current density is preferably between more than 0 mA/mm² and approximately 160 mA/mm².

In this range the radiation intensity advantageously rises proportionally to the current intensity without a shift in the main wavelength occurring.

The multiple quantum well structure is preferably produced epitaxially. Process parameters such as temperature and gas concentration which determine the epitaxy can be crucial for the properties of the multiple quantum well structure. By way of example, there are various possibilities for obtaining a smaller band gap in the second quantum well structure. Firstly, it is possible to lower the process temperature, whereby In is incorporated better, which leads to a smaller band gap. Secondly, it is possible to increase the In concentration in the process gas, which in turn leads to a better incorporation of In and a smaller band gap. A combination of the two process parameter variations is also possible. The depth of the quantum well can be set by means of the In proportion, wherein the wavelength of the radiation is all the longer, the higher the In proportion.

In the context of the application, the designation quantum well structure encompasses any structure in which charge carriers can experience a quantization of their energy states as a result of confinement. In particular, the designation quantum well structure does not comprise any indication about the dimensionality of the quantization. It therefore encompasses, inter alia, quantum wells, quantum wires and quantum dots and any combination of these structures.

A radiation-emitting semiconductor body according to the invention comprises a multiple quantum well structure as described above. Said structure preferably serves as an active layer of the radiation-emitting semiconductor body. The layers or layer sequences which form the multiple quantum well structure can be arranged on a substrate. In particular, the first layer sequence has an n-conducting layer on a side facing the substrate, while the second layer sequence has a p-conducting layer on a side remote from the substrate. It goes without saying that the semiconductor body can comprise further layers, for example cladding layers. A reflection layer suitable for reflecting the radiation emitted by the multiple quantum well structure in a direction of a coupling-out side is furthermore conceivable.

In accordance with one preferred configuration, the semiconductor body is embodied as a thin-film light-emitting diode chip.

A thin-film light-emitting diode chip is distinguished in particular by at least one of the following characteristic features:
a reflective layer is applied or formed at a first main area—facing toward a carrier element—of a radiation-generating epitaxial layer sequence, said reflective layer reflecting at least part of the electromagnetic radiation generated in the epitaxial layer sequence back into the latter;
the epitaxial layer sequence has a thickness in the region of 20 μm or less, in particular in the region of 10 μm; and
the epitaxial layer sequence contains at least one semiconductor layer with at least one area which has an intermixing structure which ideally leads to an approximately ergodic distribution of the light in the epitaxial layer sequence, that is to say that it has an as far as possible ergodically stochastic scattering behavior.

A basic principle of a thin-film light-emitting diode chip is described for example in I. Schnitzer et al., Appl. Phys. Lett. 63 (16), Oct. 18, 1993, 2174-2176, the disclosure content of which in this respect is hereby incorporated by reference.

A thin-film light-emitting diode chip is to a good approximation a Lambertian surface emitter.

In the case of a thin-film light-emitting diode chip, the growth substrate is typically stripped away. This has the advantage, for example, that in contrast to conventional light-emitting diodes which are electrically connected by means of the growth substrate or couple out the generated radiation through the growth substrate, the growth substrate does not have to have either a special electrical conductivity or a special radiation transmissivity.

A radiation-emitting component according to the invention has a radiation-emitting semiconductor body as described above. Such a component is suitable for wavelength-stable operation, in particular in the case of an increase in the current intensity and an associated increase in the radiation intensity.

In accordance with one variant, the radiation-emitting semiconductor body is arranged within a housing body. Furthermore, the semiconductor body can be embedded into an encapsulation. By means of a suitable encapsulation material it is possible to reduce radiation losses, for example, which can occur on account of total reflections at refractive index boundaries.

In accordance with a further variant, an optical element is disposed downstream of the radiation-emitting semiconductor body on a coupling-out side. In particular, the optical element is suitable for radiation shaping and can be embodied as a lens, for example.

Preferably, the radiation-emitting component is adapted for dimming. This means that the radiation intensity of the radiation-emitting component can advantageously be regulated by means of the current intensity.

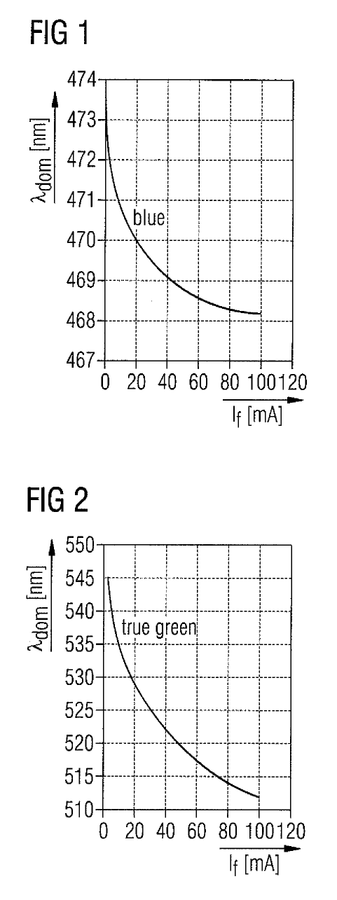

Further preferred features, advantageous configurations and developments and also advantages of a multiple quantum well structure and also of a radiation-emitting semiconductor body or component according to the invention will become apparent from the exemplary embodiments explained in greater detail below in connection with FIGS. 1 to 9.

In the figures:

FIG. 1 shows a graph illustrating the main wavelength of a conventional blue light-emitting diode as a function of the current intensity,

FIG. 2 shows a graph illustrating the main wavelength of a conventional green light-emitting diode as a function of the current intensity,

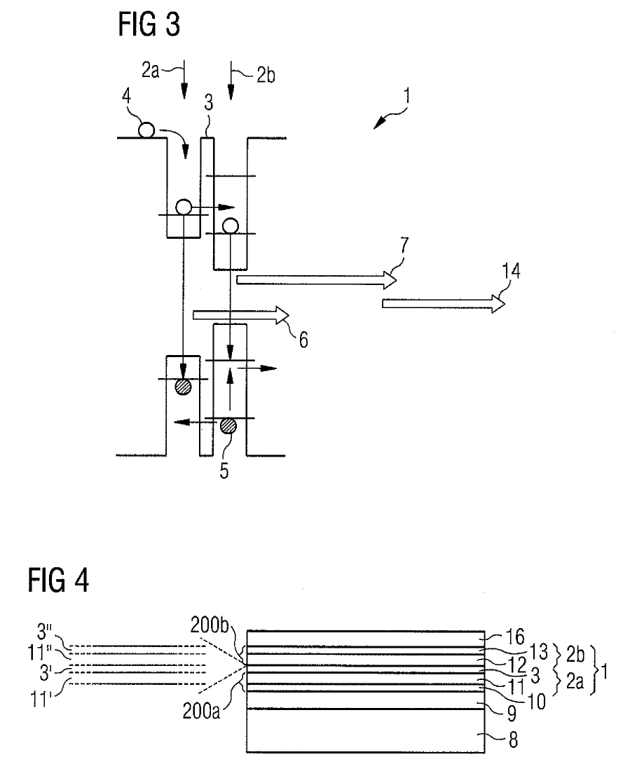

FIG. 3 shows a schematic illustration of a model of a multiple quantum well structure,

FIG. 4 shows a schematic illustration of an exemplary embodiment of a multiple quantum well structure according to the invention,

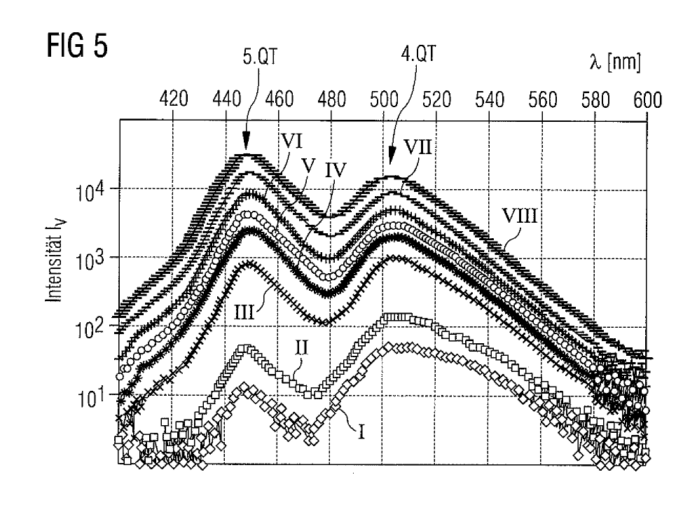

FIG. 5 shows a graph illustrating the spectral distribution of a multiple quantum well structure,

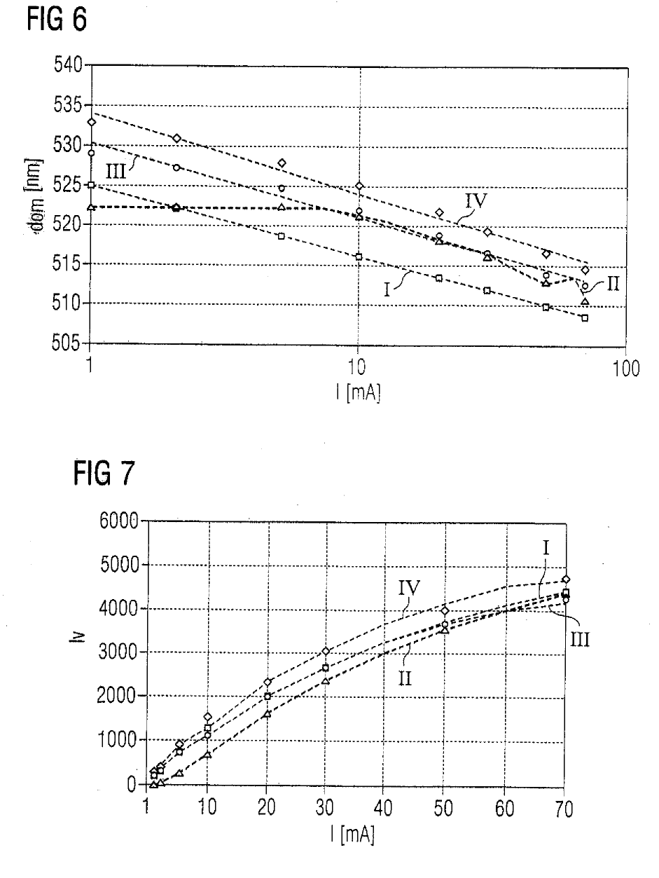

FIG. 6 shows a graph illustrating the main wavelength of various radiation-emitting semiconductor bodies as a function of the current intensity,

FIG. 7 shows a graph illustrating the radiation intensity of various radiation-emitting semiconductor bodies as a function of the current intensity,

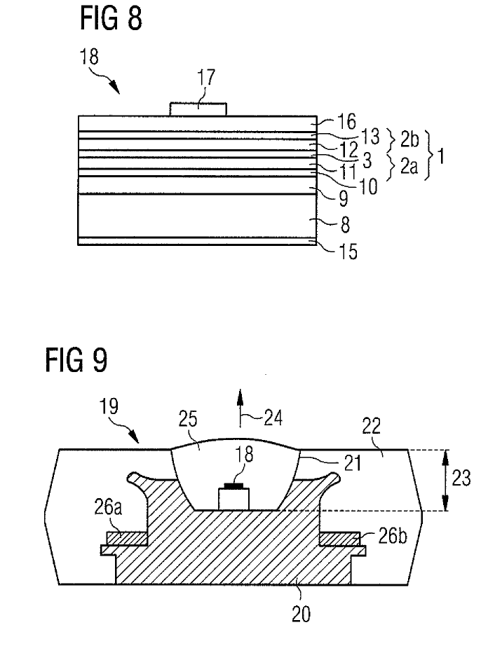

FIG. 8 shows a schematic cross section of an exemplary embodiment of a radiation-emitting semiconductor body according to the invention,

FIG. 9 shows a schematic cross section of an exemplary embodiment of a radiation-emitting component according to the invention.

As already mentioned in the general part of the description, particularly in the case of a light-emitting diode containing a nitride-based semiconductor material, a shift in the wavelength in a direction of shorter wavelengths can occur in the case of increasing energization.

FIG. 1 reveals that the main wavelength of a conventional light-emitting diode that emits light in the blue spectral range is shifted from approximately 473.5 nm to approximately 468.25 nm if the current intensity is increased from >0 mA to 100 mA.

The curve illustrated in FIG. 2 shows, in the same way as the curve illustrated in FIG. 1, that the main wavelength changes if the current intensity is increased from >0 mA to 100 mA. The measurement was carried out on a conventional light-emitting diode that emits light in the green range. In the case of an increase from >0 to 100 mA, the wavelength is shifted from approximately 545 nm to approximately 512.5 nm.

The multiple quantum well structure 1 illustrated as a model in FIG. 3 comprises a first quantum well structure 2a and a second quantum well structure 2b. Preferably, both the quantum well structure 2a and the quantum well structure 2b are based on InGaN/GaN.

Electrons 4 are impressed into the first quantum well structure 2a, which electrons can cross a barrier layer 3 with a specific probability. If this occurs, then there is the possibility of a radiative recombination with holes 5 impressed into the second quantum well structure 2b. A gap between the energy levels determines the second wavelength of the emitted radiation 7.

Like the electrons 4, the holes 5 can also cross the barrier layer 3 with a specific probability. The holes 5 which thus pass into the first quantum well structure 2a can recombine radiatively with the electrons 4 present there. The radiation 6 thus generated has a first wavelength in accordance with the gap between the relevant energy levels. Since the energy gap is larger in the first quantum well structure 2a than in the second quantum well structure 2b, the first wavelength is shorter than the second wavelength.

A radiation-emitting semiconductor body having the multiple quantum well structure 1 as an active layer emits mixed-colored radiation 14 composed of the radiation 6 emitted by the first quantum well structure 2a and the radiation 7 emitted by the second quantum well structure 2b. A main wavelength can typically be allocated to the radiation 14.

FIG. 4 illustrates a possible construction of a multiple quantum well structure 1 according to the invention. An n-conducting layer 9 is arranged on a substrate 8, which preferably contains one of the materials sapphire, SiC, GaN or GaAs. Electrons can be impressed into the multiple quantum well structure 1 by means of the n-conducting layer 9. A first layer 10, which is part of a first layer sequence 200a, is arranged on a side of the n-conducting layer 9 which is remote from the substrate 8. A well layer 11 associated with the first quantum well structure 2a and with the first layer sequence 200a is disposed downstream of the first layer 10, said well layer preferably having a thickness of between 1 nm and 5 nm. The first quantum well structure 2a is formed by means of the layer 10, the well layer 11 and the barrier layer 3. A well layer 12 and a layer 13, which form a second layer sequence 200b, are disposed downstream of the barrier layer 3 on the side remote from the substrate 8. The layer sequence 200b and the barrier layer 3 together form the second quantum well structure 2b. A p-conducting layer 16 is disposed downstream of the layer sequence 200b and is provided for impressing holes into the multiple quantum well structure 1. The layers 10 and 13 are intended as spacer layers preferably having a thickness of between 2 nm and 20 nm.

The layers 10, 11, 3, 12 and 13 preferably contain a nitride-based semiconductor material, in particular InₓGa₍₁₋ₓ₎N, where 0≦x<1.

In order to obtain a multiple quantum well structure 1 comprising more than two quantum well structures, further well layers 11′ and 11″ and also further barrier layers 3′ and 3″ can be arranged between the barrier layer 3 and the well layer 12. What material the layers 11′ and 11″ or the barrier layers 3′ and 3″ contain depends for example on what wavelength the radiation generated in the quantum well structures is intended to have.

The layers 9, 10, 11, 12, 3, 13 and 16 are produced by means of epitaxy, in particular, wherein the substrate 8 forms the growth substrate.

FIG. 5 illustrates the spectral distribution of a multiple quantum well structure comprising five quantum well structures, wherein, proceeding from an n-conducting side of the multiple quantum well structure, four quantum well structures succeed one another, said quantum well structures having a band gap corresponding to a wavelength in the green spectral range, for example of approximately 500 nm. A fifth quantum well structure arranged on the p side has a band gap corresponding to a wavelength in the blue spectral range, for example of approximately 450 nm. The current intensity increases continuously from curve I to curve VIII (curve I: 0.1 mA; curve II: 0.2 mA; curve III: 1.0 mA; curve IV: 2.0 mA; curve V: 3.0 mA; curve VI: 5.0 mA; curve VII: 10.0 mA; curve VIII: 20.0 mA). The measurements were carried out at room temperature.

While the wavelength λ[nm] of the radiation emitted by the fourth and fifth quantum well structures is plotted on the abscissa, the ordinate indicates the intensity Iᵥ (without a unit) of the emitted radiation. An intensity maximum exists at approximately 450 nm for the fifth quantum well structure and at approximately 500 nm for the fourth quantum well structure.

The crucial information that can be obtained from FIG. 5 is that the intensity Iᵥ of the radiation generated by the 5th quantum well structure, in the case of increasing energization, rises to a greater extent than the intensity of the radiation generated by the 4th quantum well structure. This can be accounted for by the fact that the main recombination center is shifted in the direction of the 5th quantum well structure in the case of increasing energization.

FIG. 6 illustrates measurement curves that were carried out on four different multiple quantum well structures each comprising four quantum well structures.

The multiple quantum well structure that yields the measurement curve IV has Si-doped barrier layers. The layer sequences of the individual quantum well structures do not differ significantly from one another with regard to the band gap. The measurement curve thus serves as a reference curve for the curves I, II and III, which were determined by means of multiple quantum well structures whose fourth quantum well structure has a different band gap than the first three quantum well structures.

The reference curve IV exhibits a shift in the main wavelength λ_{dom} in a direction of shorter wavelengths in the case of increasing energization. The curves I and III also exhibit this behavior. Only the curve II exhibits a wavelength-stable behavior of the multiple quantum well structure at least up to a current intensity of approximately 10 mA.

In the case of curve I, the band gap of the fourth quantum well structure differs from the band gap of the other quantum well structures in such a way that the difference corresponds to a wavelength approximately 10 nm shorter. This can be achieved for example by the layer sequence of the fourth quantum well structure being grown at a higher process temperature than the layer sequences of the further quantum well structures. In particular, the process temperature is 7 K higher. Preferably, all the barrier layers are Si-doped.

In the case of curve III, the band gap of the fourth quantum well structure differs from the band gap of the other quantum well structures in such a way that the difference corresponds to a wavelength approximately 10 nm longer. This can be achieved for example by the layer sequence of the fourth quantum well structure being grown at a lower process temperature than the remaining layer sequences. In particular, the process temperature is lowered by 7 K. Preferably, all the barrier layers are Si-doped.

In the case of curve II, the band gap of the fourth quantum well structure differs from the band gap of the other quantum well structures in such a way that the difference corresponds to a wavelength approximately 5 nm longer. This can be achieved for example by the layer sequence of the fourth quantum well structure being grown at a lower process temperature than the remaining layer sequences. In particular, the process temperature is lowered by 3 K. Furthermore, the barrier layer arranged before the layer sequence of the fourth quantum well structure in the growth direction is not doped.

As a result it can thus be established that wavelength-stable operation is possible by means of a slight wavelength detuning of the fourth quantum well structure relative to the first three quantum well structures.

FIG. 7 illustrates the intensity Iᵥ (without a unit) of the radiation as a function of the current intensity I [mA]. The measurements were carried out on the multiple quantum well structures already described in connection with FIG. 6.

As revealed by FIG. 7, the profile of the curve II approximates to a linear profile to a greater extent than the remaining curves.

It is advantageously possible, therefore, by means of the multiple quantum well structure whose fourth quantum well structure has a slight wavelength detuning relative to the first three quantum well structures, to obtain both wavelength-stable operation and an approximately linear increase in the radiation intensity in the case of a uniform increase in the current intensity.

The radiation-emitting semiconductor body 18 illustrated in FIG. 8 has the multiple quantum well structure 1 as an active layer. The multiple quantum well structure 1 comprises at least the first quantum well structure 2a and the second quantum well structure 2b. The semiconductor body 18 preferably comprises a multiple quantum well structure 1 which, in the case of increasing energization, enables wavelength-stable operation with at the same time an increase in the radiation-intensity. In particular, this can be achieved by the multiple quantum well structure 1 being embodied in accordance with the multiple quantum well structure that yields the measurement curves II in FIGS. 6 and 7. By way of example, the multiple quantum well structure 1 comprises four quantum well structures, wherein the band gap of the fourth quantum well structure differs from the band gap of the other quantum well structures in such a way that the difference corresponds to a wavelength approximately 5 nm longer. In this case, the first quantum well structure is arranged on the n-side, while the fourth quantum well structure is arranged on the p-side.

The multiple quantum well structure 1 is arranged between an n-conducting layer 9 and a p-conducting layer 16. Preferably, the layers 9, 10, 11, 3, 12, 13, 16 of the semiconductor body 18 are grown epitaxially on a substrate 8. In particular, the substrate 8 is electrically conductive. Consequently, an n-type electrode 15 can be arranged on a side of the substrate 8 which is remote from the layer sequence. A p-type electrode 17 is arranged on a side of the semiconductor body 18 opposite thereto. The semiconductor body 18 can be electrically connected by means of the two electrodes 15 and 17.

As an alternative, the growth substrate can be stripped away, wherein the semiconductor body is then embodied as a thin-film semiconductor body.

FIG. 9 shows a radiation-emitting component 19 having the radiation-emitting semiconductor body 18. The radiation-emitting semiconductor body 18 can be embodied for example as illustrated in FIG. 8.

The semiconductor body 18 is arranged on a heat sink 20 provided for cooling the semiconductor body 18. A service life of the component 19 can thereby be advantageously increased.

The heat sink 20 can be recessed centrally on the side on which the semiconductor body 18 is arranged, such that the semiconductor body 18 is mounted in a reflector trough 21. Side walls of the reflector trough 21 obtain a lengthening by means of a housing body 22 into which the heat sink 20 is embedded. The radiation intensity in a main emission direction 24 can advantageously be increased by means of a reflector 23 formed in this way.

For protection, the semiconductor body 18 is embedded into an encapsulation 25, which can contain for example a reaction resin such as epoxy resin or acrylic resin. The encapsulation 25 preferably fills the reflector 23. In order to concentrate the radiation generated by the semiconductor body 18, the encapsulation 25 can have a curved surface, preferably on a radiation exit side. The effect of a lens can thereby be obtained. As an alternative, an optical element can be disposed downstream of the radiation-emitting component 19 on the radiation exit side.

The radiation-emitting semiconductor body 18 is electrically connected to the electrically conductive heat sink 20; in particular, the semiconductor body 18 is soldered on or bonded on adhesively on the rear side. The heat sink 20 is furthermore electrically connected to a first connection strip 26a. Furthermore, the semiconductor body 18 is electrically connected on the front side to a second connection strip 26b, for example by means of a wire connection (not illustrated). The semiconductor body 18 can be electrically connected by means of the two connection strips 26a and 26b.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

1. A multiple quantum well structure provided for emission of radiation of a main wavelength, comprising:
a first quantum well structure for generating radiation of a first wavelength and a second quantum well structure for generating radiation of a second wavelength, which is greater than the first wavelength,
wherein
the second wavelength differs from the first wavelength in such a way that the main wavelength changes only by a predetermined maximum value in the event of a shift in the first wavelength and the second wavelength.

2. The multiple quantum well structure as claimed in claim 1, wherein
the first quantum well structure is arranged on the n-side and the second quantum well structure is arranged on the p-side.

3. The multiple quantum well structure as claimed in claim 1, wherein
the shift takes place in a direction of shorter wavelengths.

4. The multiple quantum well structure as claimed in claim 1, wherein
the second wavelength differs from the first wavelength by a magnitude in the single-digit nanometer range.

5. The multiple quantum well structure as claimed in claim 1, wherein the main wavelength lies in the short-wave spectral range, for example in the green spectral range.

6. The multiple quantum well structure as claimed in claim 1, which has respectively a layer sequence associated with the first and with the second quantum well structure,
wherein a barrier layer is arranged between the layer sequences.

7. The multiple quantum well structure as claimed in claim 6, wherein
a thickness of the barrier layer is between 4 nm and 25 nm.

8. The multiple quantum well structure as claimed in claim 6, wherein
the barrier layer is n-doped.

9. The multiple quantum well structure as claimed in claim 8, wherein the barrier layer is Si-doped.

10. The multiple quantum well structure as claimed in claim 9, wherein
the Si doping is between 10¹⁷/cm³ and 10¹⁸/cm³.

11. The multiple quantum well structure as claimed in claim 6, wherein
the barrier layer contains a nitride-based semiconductor material.

12. The multiple quantum well structure as claimed in claim 11, wherein
the barrier layer contains GaN, InGaN or AlInGan.

13. The multiple quantum well structure as claimed in claim 6, wherein
the layer sequences contain InₓGa₍₁₋ₓ₎N, and 0≦x<1.

14. The multiple quantum well structure as claimed in claim 6, wherein
the layer sequences respectively comprise a well layer, the thickness of which is between 1 nm and 5 nm.

15. The multiple quantum well structure as claimed in claim 1, which can be energized in the single-digit to two-digit milliampere range, preferably between approximately 1 mA and 15 mA.

16. The multiple quantum well structure as claimed in claim 1, which can be energized with a current density of between more than 0 mA/mm² and approximately 160 mA/mm².

17. The multiple quantum well structure as claimed claim 1, which is produced epitaxially.

18. A radiation-emitting semiconductor body having a multiple quantum well structure as claimed in claim 1.

19. The radiation-emitting semiconductor body as claimed in claim 18, wherein
the multiple quantum well structure serves as an active layer.

20. The radiation-emitting semiconductor body as claimed in claim 18, which is embodied as a thin-film light-emitting diode chip.

21. A radiation-emitting component having a radiation-emitting semiconductor body as claimed in claim 18.

22. The radiation-emitting component as claimed in claim 21, wherein
the radiation-emitting semiconductor body is arranged within a housing body.

23. The radiation-emitting component as claimed in claim 21, wherein
an optical element is disposed downstream of the radiation-emitting semiconductor body on a coupling-out side.

24. The radiation-emitting component as claimed in claim 21, which is adapted for dimming.
